(19) United States
(12) Patent Application Publication
(10) Pub. No.: US 2017/0170065 A1
(43) Pub. Date: Jun. 15, 2017

(54) CARBON FILM FORMING METHOD, CARBON FILM FORMING APPARATUS, AND STORAGE MEDIUM

(71) Applicant: TOKYO ELECTRON LIMITED, Tokyo (JP)

(72) Inventors: Masayuki KITAMURA, Nirasaki City (JP); Akira SHIMIZU, Nirasaki City (JP); Yosuke WATANABE, Nirasaki City (JP)

(21) Appl. No.: 15/377,141

(22) Filed: Dec. 13, 2016

(30) Foreign Application Priority Data
Dec. 15, 2015 (JP) 2015-244234
Nov. 10, 2016 (JP) 2016-219861

(51) Int. Cl. H01L 21/768; C23C 16/46; C23C 16/52; H01L 21/285; C23C 16/26

(52) U.S. Cl. CPC H01L 21/76883; H01L 21/76879; H01L 21/28506; C23C 16/26; C23C 16/52; C23C 16/46

(57) ABSTRACT

A carbon film forming method including: forming a first carbon film so that the first carbon film is embedded in the step shape portion by supplying a film forming gas including a hydrocarbon-based carbon source gas to the process target object; etching the first carbon film so that a V-shaped etching region, which is wide in a frontage portion of the step shape portion and becomes narrow as going to a bottom portion of the step shape portion, is formed in the first carbon film existing within the step shape portion, by supplying an etching gas to the process target object; and forming a second carbon film so that the second carbon film is embedded in the etching region by supplying a film forming gas including a hydrocarbon-based carbon source gas to the process target object, in a state where the process target object is heated.

### CROSS-REFERENCE TO RELATED APPLICATIONS

This application claims the benefit of Japanese Patent Application No. 2015-244234, filed on Dec. 15, 2015 and Japanese Patent Application No. 2016-219861, filed on Nov. 10, 2016, in the Japanese Patent Office, the disclosure of which is incorporated herein in their entirety by reference.

### TECHNICAL FIELD

The present disclosure relates to a carbon film forming method, a carbon film forming apparatus for embedding a carbon film with respect to a stepped shape and a non-transitory computer-readable storage medium.

### BACKGROUND

Carbon (C) has drawn attention as one of the materials used in a patterning process of next generation semiconductor devices. In the patterning process, embedability with respect to a stepped shape should be good.

A coating method has been studied as a film forming method having good embedability with respect to a stepped shape. However, the coating method has a problem in heat resistance.

In general, as a carbon film forming method, a plasma CVD method or a thermal CVD method has been used. However, it cannot be said that these methods are sufficient in embedability with respect to a stepped shape when the methods are used as a film in a patterning process. In particular, the plasma CVD method is capable of forming a film at a relatively low temperature but has low embedability with respect to a stepped shape.

When considering both heat resistance and embedability with respect to a stepped shape, it appears that the thermal CVD method is suitable. However, along with the miniaturization of patterns, even if conditions are adjusted in the thermal CVD method, there may be a case where defects such as voids, seams or the like are generated in a carbon film embedded into a stepped shape.

### SUMMARY

Some embodiments of the present disclosure provide to a carbon film forming method, a carbon film forming apparatus and a non-transitory computer-readable storage medium, in which defects are less likely to occur in an embedded portion when a carbon film including an embedment having a stepped shape is formed by a thermal CVD method.

According to one embodiment of the present disclosure, there is provided a carbon film forming method for forming a carbon film on a process target object having a process target surface on which a step shape portion is formed. The carbon film forming method includes: forming a first carbon film so that the first carbon film is embedded in the step shape portion by supplying a film forming gas including a hydrocarbon-based carbon source gas to the process target object, in a state in which the process target object is heated; etching the first carbon film so that a V-shaped etching region, which is wide in a frontage portion of the step shape portion and becomes narrow as going to a bottom portion of the step shape portion, is formed in the first carbon film existing within the step shape portion, by supplying an etching gas to the process target object, in a state in which the process target object is heated; and forming a second carbon film so that the second carbon film is embedded in the etching region by supplying a film forming gas including a hydrocarbon-based carbon source gas to the process target object, in a state in which the process target object is heated.

According to another embodiment of the present disclosure, there is provided a carbon film forming apparatus for forming a carbon film on a process target object having a process target surface on which a step shape portion is formed. The carbon film forming apparatus includes: a process vessel including a process chamber configured to accommodate the process target object having the process target surface on which the step shape portion is formed; a process gas supply mechanism configured to supply a gas used for processing into the process chamber; a heating device configured to heat the process target object accommodated within the process chamber; and a control part configured to control the process gas supply mechanism and the heating device, wherein the control part is configured to control the process gas supply mechanism and the heating device so that the carbon film forming method described above is implemented.

According to another embodiment of the present disclosure, there is provided a non-transitory computer-readable storage medium which operates on a computer and which stores a program for controlling a carbon film forming apparatus, wherein the program is configured to, when executed, cause the computer to control the carbon film forming apparatus so that the carbon film forming method described above is implemented.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a sectional view schematically illustrating one example of a film forming apparatus capable of implementing a film forming method according to the present disclosure.

FIG. 2 is a view illustrating a structure of a wafer to which one embodiment of the present disclosure is applied.

FIG. 3 is a flowchart illustrating a flow of a carbon film forming method according to one embodiment of the present disclosure.

FIGS. 4A to 4C are sectional views illustrating steps performed when implementing the carbon film forming method according to one embodiment of the present disclosure.

FIGS. 5A to 5D are views showing the sectional views of the steps illustrated in FIGS. 4A to 4C, SEM photos of cross sections available when the steps are performed, and an SEM photo of a cross section available after an etching step and a second carbon film forming step are repeated twice.

FIG. 6 is a timing chart illustrating an example of a sequence when Steps S3 to S6 are repeated twice or more.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <One Example of Apparatus for Implementing the Present Disclosure>

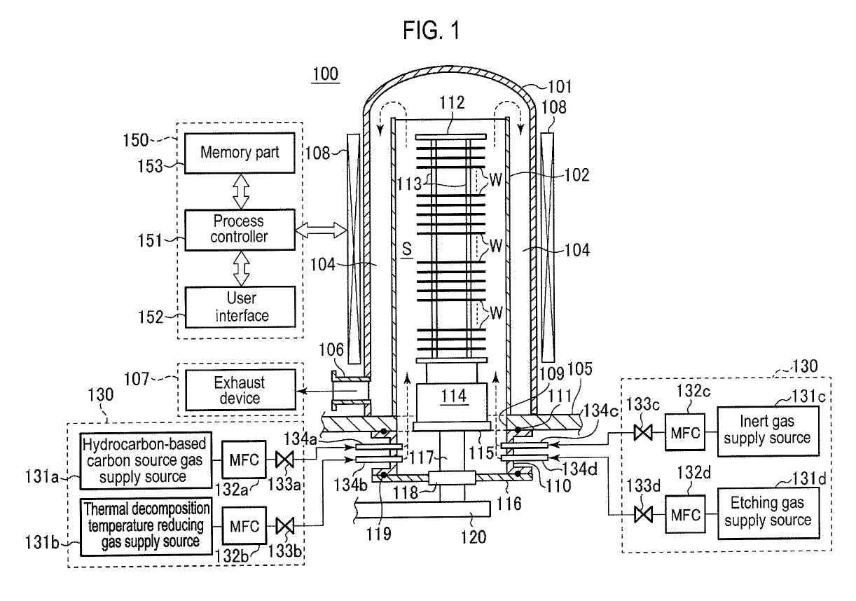

FIG. 1 is a sectional view schematically illustrating one example of a film forming apparatus capable of implementing a film forming method according to the present disclosure.

As illustrated in FIG. 1, a film forming apparatus 100 is configured as a vertical batch-type film forming apparatus. The film forming apparatus 100 includes a cylindrical outer wall 101 having a ceiling, and a cylindrical inner wall 102 installed inside the outer wall 101. The outer wall 101 and the inner wall 102 are made of, for example, quartz. An inner region of the inner wall 102 becomes a process chamber S for simultaneously processing a plurality of semiconductor wafers (hereinafter simply referred to as wafers) W which are process target objects.

The outer wall 101 and the inner wall 102 are horizontally spaced apart from each other across an annular space 104 and are connected to a base member 105 at lower ends of the outer wall 101 and the inner wall 102. An upper end of the inner wall 102 is spaced apart from the ceiling of the outer wall 101. An upper portion of the process chamber S is configured to communicate with the annular space 104. The annular space 104 communicating with the upper portion of the process chamber S serves as an exhaust path. Gases which are supplied into the process chamber S and diffused are allowed to flow from a lower portion of the process chamber S toward the upper portion of the process chamber S and are sucked into the annular space 104. An exhaust pipe 106 is connected to, for example, a lower end of the annular space 104. The exhaust pipe 106 is connected to an exhaust device 107. The exhaust device 107 is configured to include a vacuum pump or the like. The exhaust device 107 evacuates the process chamber S and adjusts an internal pressure of the process chamber S to a pressure suitable for processing.

Outside the outer wall 101, a heating device 108 is installed so as to surround a periphery of the process chamber S. The heating device 108 adjusts an internal temperature of the process chamber S to a temperature suitable for processing and simultaneously heats a plurality of wafers W.

The lower portion of the process chamber S communicates with an opening 109 formed in the base member 105. A manifold 110 formed in a cylindrical shape by, for example, stainless steel, is connected to the opening 109 via a seal member 111 such as an O-ring or the like. A lower end of the manifold 110 is formed of an opening through which a boat 112 is inserted into the process chamber S. The boat 112 is made of, for example, quartz. The boat 112 includes a plurality of posts 113. Grooves not shown are formed in the posts 113. A plurality of substrates to be processed is supported at the same time by the grooves. Thus, the boat 112 can support a plurality of, for example, 50 to 150, wafers W as substrates to be processed, in multiple stages. As the boat 112 which supports a plurality of wafers W is inserted into the process chamber S, the plurality of wafers W can be accommodated within the process chamber S.

The boat 112 is mounted on a table 115 via a quartz-made heat insulation container 114. The table 115 is supported on a rotary shaft 117 which penetrates through a lid 116 made of, for example, stainless steel. The lid 116 is configured to open and close the opening of the lower end of the manifold 110. For example, a magnetic fluid seal 118 is installed in a through-hole portion of the lid 116 and is configured to rotatably support the rotary shaft 117 while air-tightly sealing the through-hole portion of the lid 116. A seal member 119 formed of, for example, an O-ring, is installed between a peripheral portion of the lid 116 and the lower end of the manifold 110, thereby maintaining the sealability of the interior of the process chamber S. The rotary shaft 117 is mounted to a distal end of an arm 120 supported by an elevator mechanism (not shown) such as, for example, a boat elevator or the like. Thus, the boat 112 and the lid 116 are vertically moved up and down as a unit and are inserted into or extracted from the process chamber S.

The film forming apparatus 100 includes a process gas supply mechanism 130 configured to supply a gas used for processing into the process chamber S.

The process gas supply mechanism 130 according to this example includes a hydrocarbon-based carbon source gas supply source 131a, a thermal decomposition temperature dropping gas supply source 131b, an inert gas supply source 131c, and an etching gas supply source 131d.

The hydrocarbon-based carbon source gas supply source 131a is connected to a gas supply port 134a via a flow rate controller (MFC) 132a and an opening/closing valve 133a. Similarly, the thermal decomposition temperature dropping gas supply source 131b is connected to a gas supply port 134b via a flow rate controller (MFC) 132b and an opening/closing valve 133b. The inert gas supply source 131c is connected to a gas supply port 134c via a flow rate controller (MFC) 132c and an opening/closing valve 133c. The etching gas supply source 131d is connected to a gas supply port 134d via a flow rate controller (MFC) 132d and an opening/closing valve 133d. The gas supply ports 134a to 134d are respectively installed to horizontally penetrate through a sidewall of the manifold 110. The gases thus supplied are diffused into the process chamber S existing above the manifold 110.

The hydrocarbon-based carbon source gas supplied from the hydrocarbon-based carbon source gas supply source 131a is a gas for forming a carbon film by a thermal CVD method.

The hydrocarbon-based carbon source gas may include a gas containing hydrocarbon denoted by at least one of molecular formulae:

CₙH₂ₙ₊₂;

CₘH₂ₘ; and

CₘH₂ₘ₋₂,

where n is a natural number of 1 or more and m is a natural number of 2 or more.

Furthermore, the hydrocarbon-based carbon source gas may include a benzene (C₆H₆) gas.

The hydrocarbon denoted by the molecular formula CₙH₂ₙ₊0 may include:

a methane (CH₄) gas;

an ethane (C₂H₆) gas;

a propane (C₃H₈) gas;

a butane (C₄H₁₀) gas (containing other isomers);

a pentane (C₅H₁₂) gas (containing other isomers); or the like.

The hydrocarbon denoted by the molecular formula CₘH₂ₘ may include:

an ethylene (C₂H₄) gas;

a propylene (C₃H₆) gas (containing other isomers);

a butylene (C₄H₈) gas (containing other isomers);

a pentene (C₅H₁₀) gas (containing other isomers); or the like.

The hydrocarbon denoted by the molecular formula CₘH₂ₘ₋₂ may include:

an acetylene (C₂H₂) gas;

a propyne (C₃H₄) gas (containing other isomers);

a butadiene (C₄H₆) gas (containing other isomers);

an isoprene (C₅H₈) gas (containing other isomers); or the like.

The thermal decomposition temperature dropping gas supplied from the thermal decomposition temperature dropping gas supply source 131b is a gas which has functions of dropping a thermal decomposition temperature of the hydrocarbon-based carbon source gas and dropping a film forming temperature of the carbon film formed by the thermal CVD method.

As the thermal decomposition temperature dropping gas, it may be possible to suitably use a gas containing a halogen element. The halogen element may include fluorine (F), chlorine (Cl), bromine (Br), or iodine (I). In order to enhance the effect of dropping the thermal decomposition temperature, the thermal decomposition temperature dropping gas may be a gas containing a simple substance of a halogen element. A Cl₂ gas may be suitably used.

The inert gas supplied from the inert gas supply source 131c is used as a purge gas or a dilution gas. As the inert gas, it may be possible to use, for example, an N₂ gas, or a rare gas such as an Ar gas or the like.

The etching gas supplied from the etching gas supply source 131d is a gas for etching the carbon film formed for the first time. As the etching gas, it may be possible to use an oxygen-based gas such as an oxygen (O₂) gas, an ozone (O₃) gas or the like, or a halogen-based gas containing F, Br, Cl or the like, for example, a Cl₂ gas.

The film forming apparatus 100 includes a control part 150. The control part 150 includes a process controller 151 formed of, for example, a microprocessor (computer). Controls of the respective component parts of the film forming apparatus 100 are performed by the process controller 151. A user interface 152 and a memory part 153 are connected to the process controller 151.

The user interface 152 includes an input part including a touch panel display or a keyboard for enabling an operator to perform an input operation of commands in order to manage the film forming apparatus 100, and a display part including a display for visually displaying an operation situation of the film forming apparatus 100.

The memory part 153 stores a so-called process recipe which includes a control program for realizing various kinds of processes implemented by the film forming apparatus 100, through the control of the process controller 151, and a program for causing the respective component parts of the film forming apparatus 100 to implement processes pursuant to the processing conditions. The process recipe is stored in a storage medium of the memory part 153. The storage medium may include a hard disc or a semiconductor memory, or may include a portable medium such as a CD-ROM, a DVD, a flash memory or the like. In addition, the process recipe may be appropriately transmitted from other devices via, for example, a dedicated line.

If necessary, the process recipe is read out from the memory part 153 according to the operator's instructions inputted from the user interface 152. The process controller 151 causes the film forming apparatus 100 to implement the processes according to the process recipe thus read.

### <Carbon Film Forming Method>

Next, descriptions will be made on one embodiment of a carbon film forming method according to the present disclosure, which is implemented by the film forming apparatus illustrated in FIG. 1.

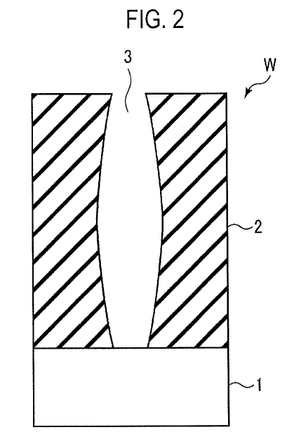

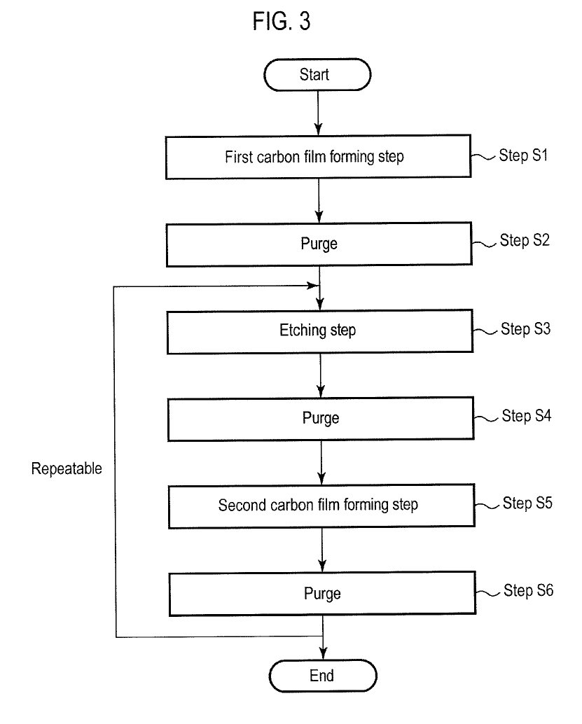

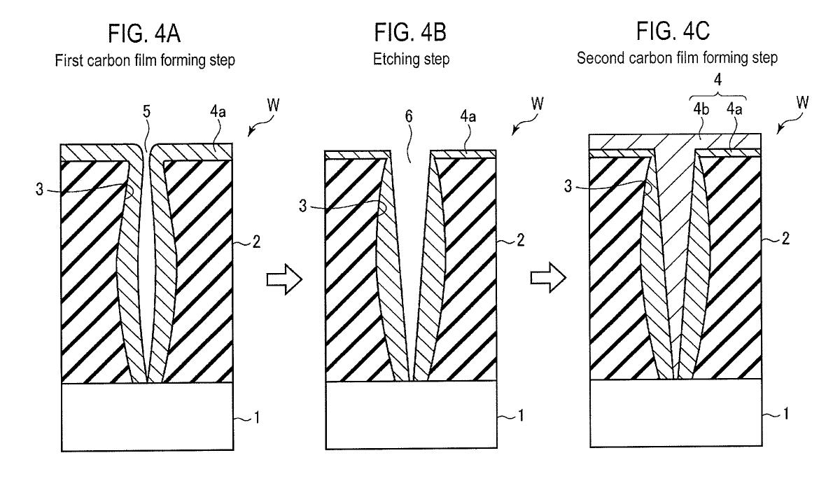

FIG. 2 is a view illustrating a structure of a wafer to which one, embodiment of the present disclosure is applied. FIG. 3 is a flowchart illustrating a flow of the carbon film forming method according to one embodiment of the present disclosure. FIGS. 4A to 4C are sectional views illustrating steps performed when implementing the carbon film forming method.

First, as illustrated in FIG. 2, a plurality of, for example, 50 to 150, wafers W, in which an interlayer insulation film 2 composed of a silicon oxide film or the like is formed on a silicon substrate 1 having a predetermined structure formed in an upper portion of the silicon substrate 1 and in which a recess 3 such as a contact hole, a via hole or the like is formed as a step shape portion in the interlayer insulation film 2, are mounted on the boat 112. The boat 112 mounted with the wafers W is loaded into the process chamber S of the film forming apparatus 100 from the lower side. The lower end opening of the manifold 110 is closed by the lid 116. In this state, the interior of the process chamber S is evacuated to maintain the interior of the process chamber S in a predetermined depressurized atmosphere. The electric power supplied to the heating device 108 is controlled to increase a wafer temperature and to maintain the wafer temperature at a process temperature. A process of forming a carbon film is performed while rotating the boat 112.

In the present embodiment, when forming the carbon film, a first carbon film forming step, an etching step and a second carbon film forming step, as main steps, are performed in situ by the film forming apparatus 100.

These steps will now be described in detail. Initially, the first carbon film forming step is implemented (Step S1). At Step S1, a first carbon film is formed by a thermal CVD method by supplying a gas containing the above-described hydrocarbon, for example, a C₅H₈ gas, as a hydrocarbon-based carbon source gas, into the process chamber S from the hydrocarbon-based carbon source gas supply source 131a and supplying a gas containing a halogen element, for example, a Cl₂ gas, as the above-described thermal decomposition temperature dropping gas, into the process chamber S from the thermal decomposition temperature dropping gas supply source 131b.

At Step S1, a first carbon film 4a formed by a thermal decomposition of the hydrocarbon-based carbon source gas is embedded in the recess 3 which is the step shape portion. The embedment is not completely performed but is finished midway (see FIG. 4A).

In the case of the CVD method, as illustrated in FIG. 2, a bowing that the recess 3 has a bulged shape in the middle portion of the recess 3 occurs and a frontage of the recess 3 is often narrowed. Moreover, the source gas is preferentially supplied to an entrance portion of the recess 3 which is the step shape portion and an overhang is likely to occur. When the bowing or the overhang occurs, if the embedment of the carbon film is continuously performed, it is highly likely that voids or seams are formed and left in the embedded carbon film. Thus, at the first carbon film forming step of Step S1, the film formation is finished before the frontage portion of the recess 3 is closed by the overhang. That is to say, as illustrated in FIG. 4A, the film formation is finished in a state in which a gap 5 exists in a central portion of the first carbon film 4a formed on the side surface of the recess 3. The timing of stopping the formation of the first carbon film 4a may be found in advance by experiments.

At Step S1, the thermal decomposition temperature of the hydrocarbon-based carbon source gas when forming the first carbon film 4a is as high as 700 to 800 degrees C. Thus, the thermal decomposition temperature of the hydrocarbon-based carbon source gas is reduced by adding the thermal decomposition temperature dropping gas. As the thermal decomposition temperature dropping gas, it may be possible to suitably use a gas containing a halogen element, for example, a Cl₂ gas. This makes it possible to set the film forming temperature to fall within a range of 350 to 450 degrees C. A flow rate ratio of the hydrocarbon-based carbon source gas to the thermal decomposition temperature dropping gas may be about 100:1 to 1000:1.

The thermal decomposition temperature dropping gas is not essential. The first carbon film may be formed using only the hydrocarbon-based carbon source gas. However, when there is a possibility that the thermal decomposition temperature of the hydrocarbon-based carbon source gas is high so that a transistor or the like formed on a silicon substrate is adversely affected during the course of the film formation, the thermal decomposition temperature of the hydrocarbon-based carbon source gas may be dropped using the thermal decomposition temperature dropping gas.

Other Conditions of Step S1 May be Set as Follows:

Process pressure: 1 to 100 Torr (133 to 13300 Pa); and

Process time: 3 to 5 min.

After Step S1, the process chamber S is evacuated by the exhaust device 107 and a purge of the process chamber S is performed by supplying a purge gas, for example, an N₂ gas, from the inert gas supply source 131c into the process chamber S (Step S2). Thus, the hydrocarbon-based carbon source gas and the thermal decomposition temperature dropping gas are discharged from the process chamber S.

After finishing the purge, an etching step is subsequently implemented (Step S3). In the etching step of Step S3, the first carbon film 4a is etched by supplying the above-described etching gas, for example, an O₃ gas, from the etching gas supply source 131d into the process chamber S (see FIG. 4B). At this time, simultaneously with the supply of the etching gas, an inert gas may be added as a dilution gas.

In the etching step of Step S3, the etching step is performed by supplying the etching gas to the first carbon film 4a from the upper side. Since it is difficult to flow the etching gas into the gap 5, an upper portion of the gap 5 is etched more preferentially than a bottom portion of the gap 5. Thus, as illustrated in FIG. 4B, the etching region 6 has a V-like shape with the frontage portion being wide and becoming narrow toward the bottom portion.

From the viewpoint of enhancing the throughput, an etching temperature may be set equal to the heating temperature of the wafer W heated by the heating device 108 at Step S1. However, when the thermal decomposition temperature dropping gas is not used, the film forming temperature of the carbon film is about 700 to 800 degrees C. If the etching step is performed in this temperature range, there is a possibility that an etching rate becomes too high. For that reason, the temperature during the formation of the first carbon film of Step S1 is set at 350 to 450 degrees C. using the thermal decomposition temperature dropping gas and the etching of Step S3 is performed at a temperature which falls within a range of 350 to 450 degrees C.

Other Conditions of Step S3 May be Set as Follows:

Process pressure: 0.2 to 4.5 Torr (26.6 to 598.5 Pa); and

Process time: 3 to 5 min.

After Step S3, the process chamber S is evacuated by the exhaust device 107 and a purge of the process chamber S is performed by supplying a purge gas, for example, an N₂ gas, from the inert gas supply source 131c into the process chamber S (Step S4). Thus, the etching gas is discharged from the process chamber S.

After finishing the purge, a second carbon film forming step is implemented (Step S5). Similar to Step S1, a second carbon film at Step S5 is formed by a thermal CVD method by supplying a gas containing hydrocarbon, for example, a C₅H₈ gas, as a hydrocarbon-based carbon source gas, into the process chamber S from the hydrocarbon-based carbon source gas supply source 131a and supplying a gas containing a halogen element, for example, a C1₂ gas, as the thermal decomposition temperature doping gas, into the process chamber S from the thermal decomposition temperature doping gas supply source 131b. At this time, the film forming temperature may be set at the same temperature as the temperature of the first carbon film forming step of Step S1 and the temperature of the etching step of Step S3.

At Step S5, the second carbon film 4b formed by the thermal decomposition of the hydrocarbon-based carbon source gas is embedded in the etching region 6 (see FIG. 4C).

At this time, the etching region 6 has a V-like shape with the frontage portion being wide and the bottom portion being narrow. Thus, when the second carbon film 4b is embedded by the thermal CVD method, the carbon source gas is likely to reach the bottom portion of the etching region 6. It is therefore possible to effectively prevent generation of voids or seams within the second carbon film 4b.

In this way, the carbon film 4 composed of the first carbon film 4a and the second carbon film 4b can be embedded in the recess 3 without generating voids or seams.

At Step S5, similar to the formation of the first carbon film 4a at Step S1, the thermal decomposition temperature of the hydrocarbon-based carbon source gas may be dropped by adding the thermal decomposition temperature dropping gas, thereby setting the film forming temperature at, for example, 350 to 450 degrees C. However, the thermal decomposition temperature dropping gas is not essential. The second carbon film may be formed using only the hydrocarbon-based carbon source gas. Other film forming conditions may be the same as the forming conditions of the first carbon film 4a of Step S1. Under these conditions, the second carbon film 4b may be formed.

After Step S5, the process chamber S is evacuated by the exhaust device 107 and the purge of the process chamber S is performed by supplying a purge gas, for example, an N2 gas, from the inert gas supply source 131c into the process chamber S (Step S6). Thus, the hydrocarbon-based carbon source gas and the thermal decomposition temperature dropping gas are discharged from the process chamber S.

The formation of the carbon film may be completed by performing the first carbon film forming step, the etching step and the second carbon film forming step once as described above. However, the etching step and the second carbon film forming step may be repeated twice or more. Specifically, as illustrated in FIG. 3, after performing the purge of Step S6, Steps S3 to S6 may be repeated twice or more. By repeating the etching step and the second carbon film forming step twice or more, it is possible to more effectively suppress generation of voids or seams.

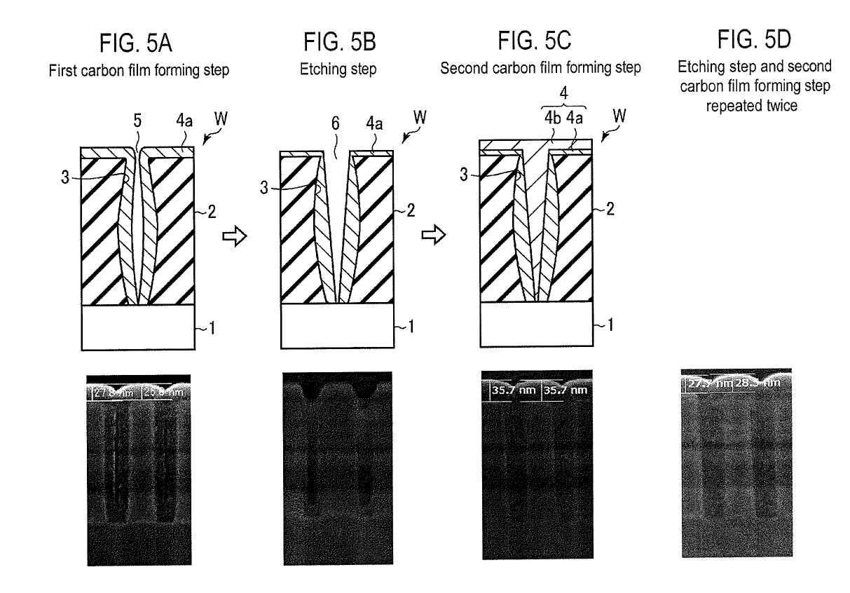

This will be described with reference to FIGS. 5A to 5D. FIGS. 5A to 5D are views showing the sectional views of the steps illustrated in FIGS. 4A to 4C, SEM photos of cross sections available when the steps are performed, and SEM photo of a cross section available after the etching step and the second carbon film forming step are repeated twice.

As shown in the SEM photo of FIG. 5C, when the first carbon film forming step, the etching step and the second carbon film forming step are performed only once, voids or seams do not completely disappear. As shown in the SEM photo of FIG. 5D, it can be noted that, by repeating the etching step and the second carbon film forming step twice, residues are removed and voids or seams are almost completely gone.

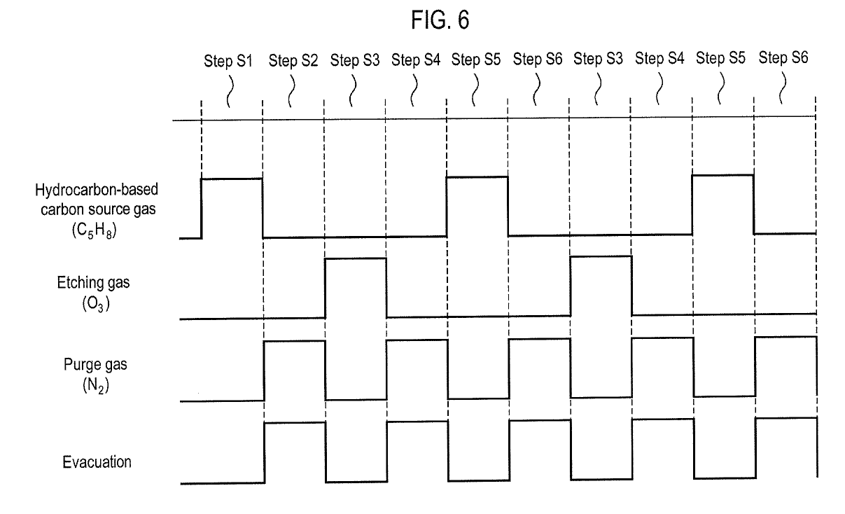

A sequence at the time of repeating Steps S3 to S6 twice or more is indicated by, for example, a timing chart illustrated in FIG. 6. That is to say, it is possible to perform the sequence in which the supply of the hydrocarbon-based carbon source gas and the supply of the etching gas are repeated with the purge interposed therebetween.

As described above, according to the present embodiment, the first carbon film 4a is embedded midway in the recess 3 at the first carbon film forming step. Then, the etching region 6 having the V-like shape is formed in the first carbon film 4a at the etching step. Thereafter, the second carbon film 4b is embedded in the etching region 6 having the V-like shape at the second carbon film forming step. It is therefore possible to form the carbon film 4 within the recess 3 in a void-free state and a seam-free state.

Since the first carbon film forming step, the etching step and the second carbon film forming step can be performed in situ within single film forming apparatus 100, it is possible to embed the carbon film with high throughput. In addition, by performing the first carbon film forming step, the etching step and the second carbon film forming step at the same temperature, it is possible to further improve the throughput without requiring time to change the film forming temperature.

### <Other Applications>

While an embodiment of the present disclosure has been described above, the present disclosure is not limited to the above-described embodiment but may be diversely modified without departing from the spirit thereof.

For example, in the above-described embodiment, there has been illustrated an example in which the carbon film is formed using the vertical batch-type film forming apparatus. However, it is possible to use a single-substrate-type film forming apparatus or a batch-type film forming apparatus other than the vertical batch-type film forming apparatus.

Furthermore, in the above-described embodiment, descriptions have been made by taking a semiconductor wafer as an example of the process target object. However, the process target object is not limited to the semiconductor wafer. It goes without saying that the present disclosure may be applied to other process target objects, such as a glass substrate used for an FPD (flat panel display) such as a liquid crystal display device or the like, a ceramic substrate, or the like.

According to some embodiments of the present disclosure, it is possible to form the carbon film within the step shape portion in a void-free state and a seam-free state by embedding the first carbon film into the step shape portion at the first carbon film forming step, then forming a V-shaped etching region in the first carbon film at the etching step, and then embedding the second carbon film in the V-shaped etching region at the second carbon film forming step.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A carbon film forming method for forming a carbon film on a process target object having a process target surface on which a step shape portion is formed, comprising:
forming a first carbon film so that the first carbon film is embedded in the step shape portion by supplying a film forming gas including a hydrocarbon-based carbon source gas to the process target object, in a state in which the process target object is heated;
etching the first carbon film so that a V-shaped etching region, which is wide in a frontage portion of the step shape portion and becomes narrow as going to a bottom portion of the step shape portion, is formed in the first carbon film existing within the step shape portion, by supplying an etching gas to the process target object, in a state in which the process target object is heated; and
forming a second carbon film so that the second carbon film is embedded in the etching region by supplying a film forming gas including a hydrocarbon-based carbon source gas to the process target object, in a state in which the process target object is heated.

2. The method of claim 1, wherein forming a first carbon film, etching the first carbon film and forming a second carbon film are continuously performed within the same process chamber formed in the same film forming apparatus.

3. The method of claim 2, wherein forming a first carbon film, etching the first carbon film and forming a second carbon film are performed at the same temperature.

4. The method of claim 2, wherein purging the process chamber is performed between forming a first carbon film and etching the first carbon film, between etching the first carbon film and forming a second carbon film, and after forming a second carbon film.

5. The method of claim 1, wherein etching the first carbon film and forming a second carbon film are repeated multiple times.

6. The method of claim 1, wherein, when forming a first carbon film and forming a second carbon film, the film forming gas includes the hydrocarbon-based carbon source gas and a thermal decomposition temperature dropping gas to drop a thermal decomposition temperature of the hydrocarbon-based carbon source gas and to set a film forming temperature at 350 to 450 degrees C.

7. The method of claim 1, wherein forming a first carbon film is finished before the carbon film is completely embedded in the step shape portion and in a state in which a gap is formed.

8. The method of claim 1, wherein the etching gas is an oxygen-based gas including an oxygen (O₂) gas or an ozone (O₃) gas, or a halogen-based gas containing a halogen element.

9. The method of claim 1, wherein the hydrocarbon-based carbon source gas is a gas containing hydrocarbon denoted by at least one of molecular formulae:
CₙH₂ₙ₊₂;
CₘH₂ₘ; and
CₘH₂ₘ₋₂;
where n is a natural number of 1 or more and m is a natural number of 2 or more.

10. A carbon film forming apparatus for forming a carbon film on a process target object having a process target surface on which a step shape portion is formed, comprising:
a process vessel including a process chamber configured to accommodate the process target object having the process target surface on which the step shape portion is formed;
a process gas supply mechanism configured to supply a gas used for processing into the process chamber;
a heating device configured to heat the process target object accommodated within the process chamber; and
a control part configured to control the process gas supply mechanism and the heating device,
wherein the control part is configured to control the process gas supply mechanism and the heating device so that the carbon film forming method of claim 1 is implemented.

11. A non-transitory computer-readable storage medium which operates on a computer and which stores a program for controlling a carbon film forming apparatus, wherein the program is configured to, when executed, cause the computer to control the carbon film forming apparatus so that the carbon film forming method of claim 1 is implemented.
